(19) United States
(12) Patent Application Publication
(10) Pub. No.: US 2002/0066851 A1
(43) Pub. Date: Jun. 6, 2002

(54) OPTICAL AND IMAGES SENSOR SUBASSEMBLY ALIGNMENT AND MOUNTING METHOD

(76) Inventors: ROBERT J. HENNICK, AUBURN, NY (US); COLLEEN P. GANNON, JORDAN, NY (US); KLAUS KREMMIN SR., CHURCHVILLE, NY (US)

Correspondence Address: WALL MARJAMA & BILINSKI, 101 SOUTH SALINA STREET, SUITE 400, SYRACUSE, NY, 13202, US

(21) Appl. No.: 09/312,479

(22) Filed: May 17, 1999

(51) Int. Cl. H01L 27/00; H01J 3/14

(52) U.S. Cl. 250/216

(57) ABSTRACT

The invention is a method and associated apparatus for mounting an optical subassembly of an optical reading device onto an image sensor subassembly of an optical reading device with use of solder as a bonding material. In accordance with the invention, solderable surfaces are formed on either or both an optical subassembly and an image sensor subassembly. For mounting of the optical subassembly onto the image sensor subassembly, an assembly station worker aligns optical and imaging elements by observing indicia corresponding to electrical signals generated by the image sensor under controlled conditions, and then, when alignment is established, solders the subassemblies at any interfaces that are defined by the solderable surfaces. The solderable surfaces of either or both the optical or image sensor assemblies may be made in irregular configurations having increased surface areas per unit three dimensional space relative to that of a smooth surface. In one embodiment, the solderable surfaces include a pin on one of the subassemblies and a hole on the remaining subassembly.

### FIELD OF THE INVENTION

The invention relates generally to optical reading devices and particularly to a method and apparatus for mounting an optical subassembly to an image sensor subassembly in an optical reader.

### BACKGROUND OF THE PRIOR ART

The characteristics exhibited by optical components, such as lenses, and imaging components, such as image sensor chips, of optical reading devices cannot be controlled inexpensively with a great deal of precision during manufacturing of such components. As a result, characteristics of both optical and imaging elements tend to vary from element to element among like styled components. For example, the location of a lens centerline of a particular style of lens will vary from lens to lens of that style. Similarly, the location of a pixel plane of a particular style of image sensor chip will vary from chip to chip of that particular style. Because proper operation of many types of optical readers requires alignment between optical and imaging elements, these manufacturing tolerances present a challenge to the manufacture of optical reading devices. An inherent problem with the assembly of optical reading devices requiring high resolution imaging is the alignment of an optical component, such as a lens, with an imaging component, such as an image sensor.

In optical reading devices, components of a receive optical system, and image sensor chips of optical readings systems are both commonly mounted to substantially rigid members. Receive optical lenses or other optical elements are often mounted to housings referred to as “lens frames” or “lens holders”, while the image sensor chip of most reading devices is mounted to a printed circuit board (PCB) or another substantially rigid member. The combination of the optical elements and their associated rigid member is referred to herein as an “optical subassembly” while the combination of an image sensor and its associated rigid member is referred to herein as an “image sensor subassembly.”

One common method for mounting of an optical subassembly to an image sensor subassembly involves adhering the optical subassembly to the image sensor assembly with use of an adhesive material such as an organic based glue, a “quick bonding” glue such as a cyanoacrylate adhesive, or an epoxy based adhesive. Unfortunately, use of adhesives to bond the subassemblies together presents a number of potential problems. For example, “quick bonding” glues tend to emit gasses which can condense on optical components, organic based glues tend to have long settling times, while epoxies require extremely precise and careful application to surfaces requiring bonding. In addition, organic based glues and epoxies require that external clamping forces be applied to the optical and imaging subassemblies during the assembly process. Another problem with use of adhesives is that adhesives, in general, have relatively fast rates of thermal expansion. As a result, internally and externally generated heat can weaken the bonding force of adhesive material over the course of time to cause misalignment of optical and image sensor subassemblies.

There is a need for an optical and image sensor assembly mounting method which facilitates good production speed and good and durable alignment between the optical and imaging elements of the optical and image sensor subassemblies.

### SUMMARY OF THE INVENTION

According to its major aspects and briefly stated the present invention relates to a method and associated apparatus for mounting an optical subassembly to an image sensor subassembly of an optical reader device so as to provide in a short assembly time, secure attachment of the subassemblies while facilitating alignment between optical elements of the optical subassembly and imaging elements of the image sensor subassembly.

In the present invention, an optical subassembly carrying at least one optical element and an image sensor subassembly carrying at least one image sensor are attached to one another with use of solder material. Use of solder material for attaching an optical subassembly to an image sensor subassembly provides several advantages. For example, use of solder material increases the speed with which the subassemblies may be attached together, and allows the subassemblies to be readily detached if necessary. Furthermore, use of solder simplifies the assembly process in that use of solder alleviates the need to apply substantial external clamping forces to the subassemblies during assembly.

For adapting the subassemblies to be soldered together, at least one solderable surface is formed on at least one of the optical and image sensor subassemblies. In a preferred embodiment, at least one solderable surface of a first subassembly is formed to be complementary with at least one surface of the remaining subassembly so that the surfaces oppose one another when the subassemblies are engaged. Solderable surfaces of the subassemblies may be smooth, but preferably are of irregular configurations. Forming the solderable surfaces in irregular configurations increases the surface area of the solderable surface within a given three dimensional space, thereby increasing the securing force with which the subassemblies can be secured to one another with use of solder. In one preferred embodiment, the solderable surfaces of the subassemblies include a pin on one of the subassemblies, and complementary hole on the other subassembly.

For mounting of the subassemblies to one another, the subassemblies may be positioned in a mounting fixture and then moved in proximity with one another. When the subassemblies are in the mounting fixture, an assembly station worker may then expose the image sensor to a predetermined test target, and observe indicia of the electrical signals generated by the image sensor. These indicia may comprise, for example, a video display corresponding to the image sensor output. An assembly station worker adjusts the relative positioning of the subassemblies until indicia indicating alignment between optical and imaging elements of the subassemblies is observed. When alignment-indicating indicia is observed, the subassemblies are soldered together at the interfaces between the solderable surfaces of the subassemblies using conventional soldering methods.

These and other details, advantages and benefits of the present invention will become apparent from the detailed description of the preferred embodiment hereinbelow.

### BRIEF DESCRIPTION OF THE DRAWINGS

The preferred embodiment of the invention will now be described, by way of example only, with reference to the accompanying Figures wherein like members bear like reference numerals and wherein:

FIG. 1A is a front perspective view of an exemplary optical and image sensor assembly assembled in accordance with the invention;

FIG. 1B is a rear perspective view of an exemplary optical and image sensor assembly assembled in accordance with the invention;

FIG. 1C is a cross sectional view taken along line C-C of FIG. 1B;

FIG. 2A is a front perspective view of an exemplary optical subassembly in accordance with the invention;

FIG. 2B is a rear perspective view of an exemplary optical subassembly in accordance with the invention;

FIG. 3A is a front perspective view of an exemplary image sensor subassembly in accordance with the invention;

FIG. 3B is a rear perspective view of an exemplary image sensor subassembly in accordance with the invention;

FIG. 4A illustrates an exemplary implementation of an assembly according to one invention in a document reader;

FIG. 4B illustrates an exemplary implementation of an assembly according to the invention in a hand held optical reader;

FIG. 5 is a perspective view of an exemplary mounting fixture which may be used for assembly of an optical and image sensor assembly in accordance with the invention.

### DETAILED DESCRIPTION

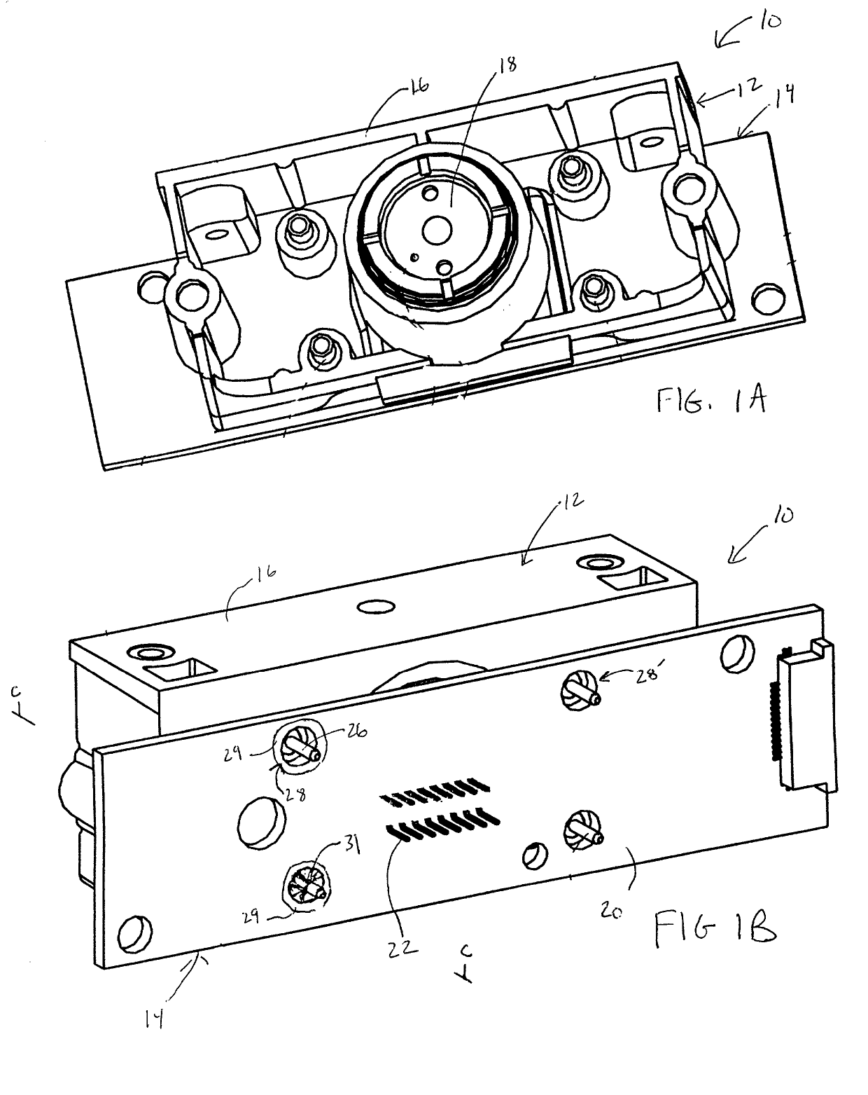

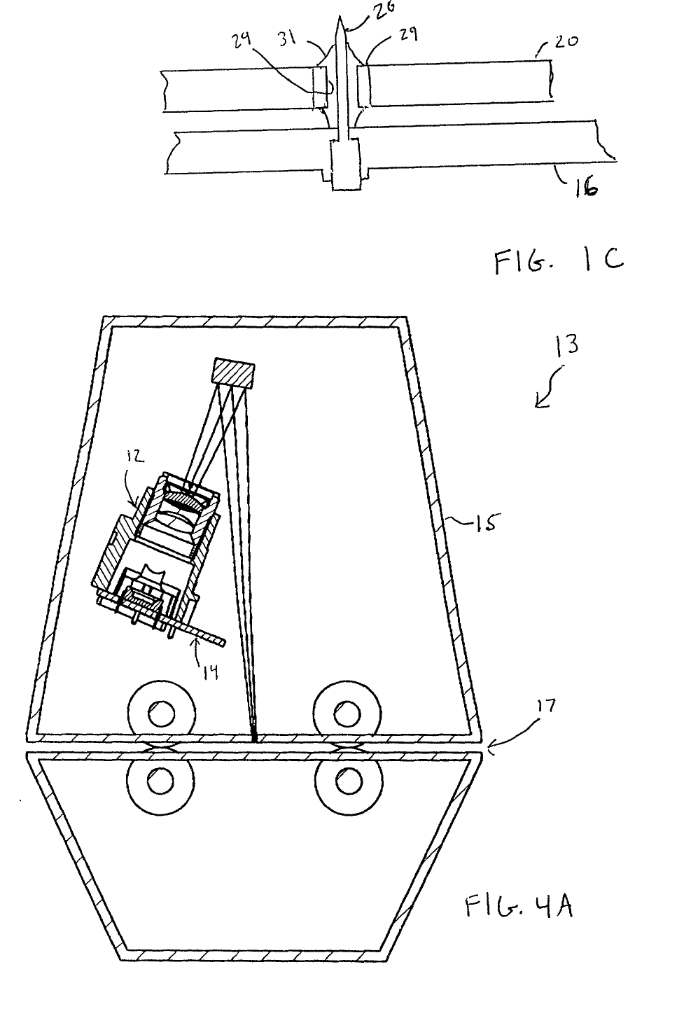

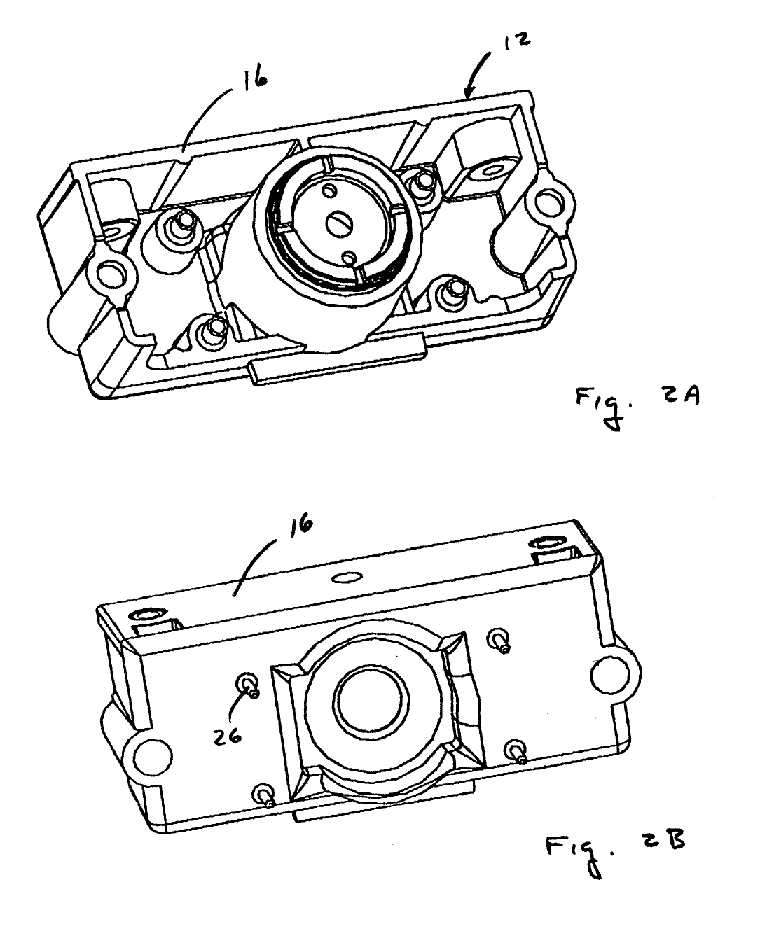

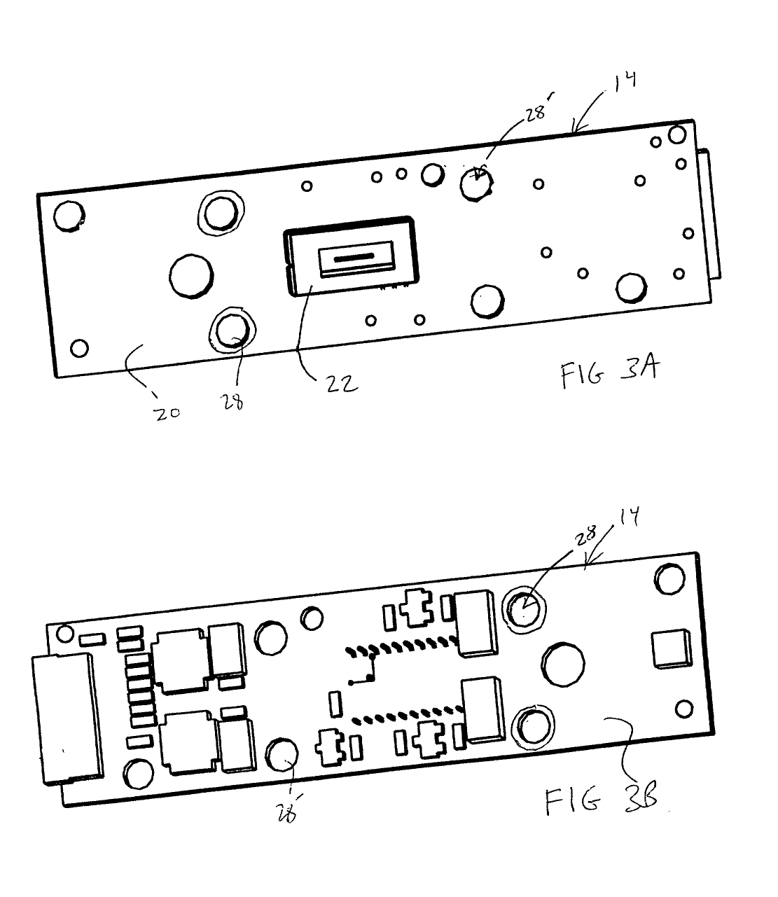

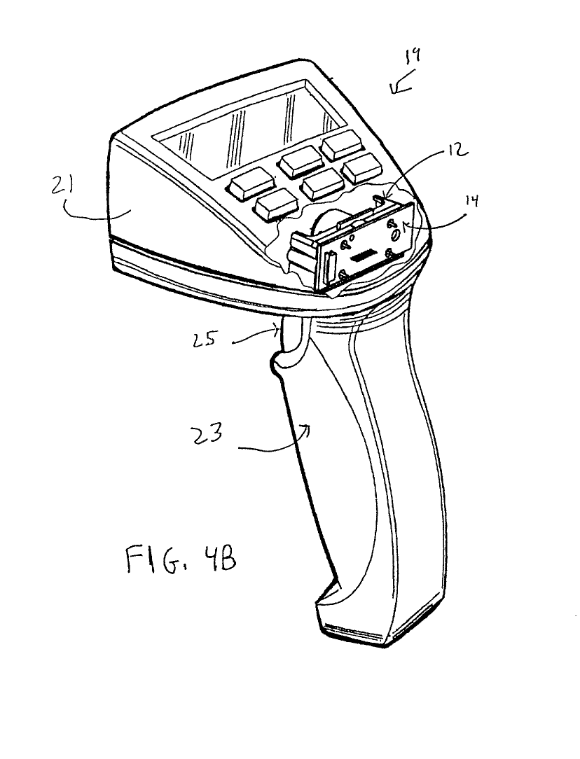

The optical subassembly to image sensor subassembly mounting method of the invention is described with reference to FIGS. 1A through 3B. An assembled optical and image sensor assembly is shown in FIGS. 1A and 1B. Optical and image sensor assembly 10 includes optical subassembly 12 and image sensor subassembly 14. Optical subassembly 12 includes a substantially rigid member 16 adapted to hold at least one optical component, which in the specific embodiment of FIGS. 1A through 3B is provided by a lens 18. While the particular type of lens mounted in substantially rigid member 16 is a “lens barrel” type lens, it will be understood that rigid member 16 may also be configured to house other types of optical components such as mirrors and prisms, and combinations of optical components. Optical and image sensor assembly 10 also includes image sensor subassembly 14. As best seen in FIG. 3A, image sensor subassembly 14 includes substantially rigid member 20, shown as being provided by a printed circuit board (PCB), which receives an image sensor 22 and which typically includes processing circuitry for processing image signals generated by image sensor 22. Image sensor 22 may be a 1D or 2D image sensor manufactured in any one of several available technologies including CCD, CMOS, NMOS, PMOS, CID or CMD technologies. It is understood that substantially rigid member 20 supporting image sensor 22 may be a member other than a PCB. For example, an image sensor may be mounted to a substantially rigid member provided by a mounting plate or bracket which in turn is attached to a PCB, a substantially rigid member extending from a PCB or another substantially rigid member of the device in which the subassembly is incorporated.

Now referring to particular aspects of the present invention, the present invention relates to a method and apparatus for precision alignment and mounting of an optical subassembly to an image sensor subassembly. Precision alignment mounting of an optical assembly in relation to an image sensor subassembly is required for applications requiring high resolution or otherwise high quality imaging. An optical and image sensor assembly assembled in accordance with the invention may be incorporated in virtually any optical reading device adapted to capture image data. For example, as is shown in FIG. 4A, assembly 10 may be incorporated in a fixed position document reader, such as a security document reader 13 of the type having a housing 15 and a document feed path 17, or else, as is indicated in FIG. 4B, assembly 10 may be incorporated in a hand held optical reader such as a bar code reader 19 having a housing 21 handle 23 and a trigger switch 25. Of course, assembly 10 may also be incorporated in other types of optical reading devices adapted to capture images such as video cameras and digital cameras.

Document reading devices of various types in which an optical and image sensor assembly according to the invention may be incorporated are described in, for example, in application Ser. No. 09/087,337 entitled “Methods for Processing Security Documents” filed May 29, 1998 and incorporated by reference herein. Examples of hand held optical reading devices of various types in which an assembly according to the invention may be incorporated are described, for example, in U.S. Pat. No. 5,825,006 entitled “Optical Reader Having Improved Autodiscrimination Features” issued Oct. 20, 1998, also incorporated by reference herein.

The characteristics exhibited by optical components, such as lenses, and imaging components, such as image sensor chips, of optical reading devices cannot be controlled inexpensively with a great deal of precision during manufacturing of such components. As a result, characteristics of certain optical and imaging elements will vary from element to element of like styled components. For example, the location of a lens centerline of a particular style of lens will vary from lens to lens of that style. Similarly, the location of a pixel plane of a particular style of image sensor chip will vary from chip to chip of that particular style. Because some precision applications require precise alignment between an optical component and an imaging component (typically between a lens and an image sensor), the manufacturing tolerance inherent in optical and image sensor devices present a challenge to the assembly of optical reading devices.

The present invention includes complementarily formed optical and image sensor subassemblies adapted to be moved relative to one another during the assembly process until alignment is established between optical and imaging components of the assemblies. The assemblies are further adapted so that, when alignment is established, the assemblies may be fixedly secured together in a position at which alignment is achieved. Whether or not proper alignment is established may be determined by analysis of indicia corresponding to electrical signals generated by the image sensor. Proper alignment between imaging and optical components may be indicated on the basis of the image sensor assembly generating electrical signals that satisfy a predetermined criteria indicating alignment between optical and imaging components under controlled conditions.

In one embodiment of the invention, optical and image sensor subassemblies are provided with complementarily solderable metallic surfaces to facilitate soldering of the optical and image sensor assemblies together when alignment between the assemblies respective optical and image sensor components is established. Soldering of the optical and image sensor assemblies provides numerous advantages. Solder has a settling time significantly shorter than many types of adhesive material, such as organic glues and many epoxy based adhesives. Accordingly, use of solder as a bonding material allows optical and image sensor subassemblies to be attached together in fixed relation more quickly than a method involving use of adhesives. This is a significant benefit considering that mounting of an optical subassembly onto an image sensor subassembly typically requires use of a mounting fixture as will be described hereinbelow. The faster settling time allows for an increased number of assemblies to be loaded into a mounting fixture for assembly within a given time frame. In addition to providing a fast settling or “tack” time, solder facilitates simplified detachment of attached assemblies. Assemblies secured with use of solder can readily be detached simply by heating the solder. Detachment of an optical subassembly from an image sensor subassembly in an optical and images sensor assembly may be beneficial for servicing, cleaning or for realignment of components of the assembly which have become misaligned over time. Another benefit of solder as a bonding material is the slow rate of thermal expansion of solder relative to other types of bonding materials, such as adhesives. The slow rate of thermal expansion reduces the likelihood that internal or externally generated heat will degrade the security of the attachment over time, and therefore reduces the likelihood that aligned optical and imaging elements will become misaligned over time. Still another benefit yielded by the use of solder as a bonding material is that solder may be applied to bond the subassemblies together without a substantial clamping force being applied to the subassemblies during the assembly process. This is in contrast to attachment methods involving use of adhesives which normally require that a substantial external clamping force be applied to the assemblies during the assembly process. The soldering of the optical and image sensor assemblies may be carried out with any available type of solder material which may include such materials as zinc, copper, tin, lead, bizmuth, and other metals. The solder material may also include a flux core. One particular material which may be used with the invention is a solder material comprising a combination of tin, lead, bizmuth, and a flux core.

For adapting optical subassembly 12 and image sensor subassembly 14 to be assembled together with use of solder, at least one pair of opposing solderable surfaces may be formed on the optical subassembly and the image sensor subassembly respectively. Substantially rigid members 16 and 20 of the optical subassembly and the image sensor subassemblies typically comprise non-solderable material. A preferred material for member 16 is plastic such as non-conductive high temperature thermoplastic which may be formed by a process of injection molding. Where substantial rigid member 20 of image sensor assembly 14 is provided by a PCB then member 20 may comprise a fiberglass laminate structure formed by any available PCB fabrication method. Metallic or otherwise solderable surfaces may be formed on the optical assembly and the image sensor assembly by a number of different methods. Solderable surfaces may be formed on non-solderable material for example, by overmolding non-solderable material onto the solderable surfaces, by plating the solderable surfaces on to the non-solderable material, by adhering a solderable material to a non-solderable material with use of adhesives, or by insert molding members having solderable surfaces into members comprising non-solderable material. Solderable surfaces may also be formed on non-solderable material by way of adapting a member having a solderable surface to be attached to non-solderable material by friction-holding or by other mechanical forces. For example, a structure bearing a solderable surface may comprise a threaded screw section for threading into non-solderable material. A solderable surface in one embodiment of the invention may be an exposed portion of a threaded screw which is threaded into non-solderable material. While it is normally required that substantially rigid member 20 comprise an insulating material, substantially rigid member 16 of optical subassembly 12 may be made entirely of a solderable material.

In a simplified embodiment of the invention, the at least one pair of complementary opposing pairs of solderable surfaces are smooth and flat, and the assemblies are made so that at least a portion of the opposing surfaces remain opposed to one another while the assemblies are adjusted between various relative positions before being fixedly adhered to one another.

In possible alternative embodiments, the solderable surfaces may be formed in irregular configurations having surface areas per unit, three dimensional space relatively larger than that of a flat, smooth surface. By increasing the surface area of the solderable surfaces of either or both the optical assembly or image sensor assembly, the securing force with which the optical assembly is held in relation to the image sensor assembly with use of solder is increased. Irregular configurations of the solderable surfaces may include dimpled, ridged, or otherwise jagged, coarse, or rough surfaces. An irregular configurationed solderable surface may also comprise, for example, a cavity or depression, a hole, or a single dimple, perturbation, post or pin.

One preferred embodiment of the invention is described with reference to FIGS. 1A through 3B. In the example of FIGS. 1A through 3B, the solderable surfaces of the optical and image sensor assemblies include, on one of the assemblies a pin 26, which may be a gold-plated pin and on another of the assemblies a complementarily formed hole 28, 28′. The example of FIGS. 1A through 3B include four pin and hole combinations formed about the periphery of the optical and image sensor assembly 10. The diameter of each pin 26 is smaller than the diameter of its associated hole 28, 28′ to allow adjustment of the optical subassembly relative to the image sensor subassembly before the optical subassembly is mounted in a fixed position relative to the image sensor subassembly. While the example of FIGS. 1A through 3B shows pins being formed on optical subassembly 12 and holes being formed on image sensor subassembly 14, it will be understood that pin and hole arrangements may be formed in any combination on the optical subassembly and on the image sensor subassembly. For example, the image sensor subassembly may include pins only or each of the subassemblies 12 and 14 may include both pins and holes.

When a pin and hole arrangement is implemented it is preferred that solderable material 29 be formed about the hole, as shown by hole 28, by way of one of the above mentioned methods so that solder applied during attachment bonds both the exposed surfaces about pin 26 and about hole 28. However, it will be understood that a strong securing force can be provided by way of a pin and hole arrangement with use of solder, without formation of a solderable surface about the hole as shown by hole 28′. This is because solder which bonds only to pin 26 which does not bond to a surface about hole 28′ will nevertheless apply a compression force to member 16 to thereby secure optical subassembly 12 in fixed relation to image sensor subassembly 14. Variations of hole configurations for using in pin and hole arrangements of the invention are described with reference to FIG. 1B. Hole 28 includes a solderable surface 29 which may be provided, for example, by a “plated through” hole of a PCB, which are well known to those skilled in PCB fabrication arts. Hole 28′, meanwhile, is a hole which does not comprise a solderable surface. Pins 26 may be readily formed in subassembly 16 or subassembly 20 by way of insert molding, or by forming threads in pins 26 and threading pins 26 into subassembly 16 or 20.

A pin and hole arrangement in a state after application of solder material to the arrangement is shown in FIGS. 1B and 1C. FIG. 1B shows a perspective view of a pin and hole arrangement having solder material 31 applied to the arrangement, which FIG. 1C show a cross sectional view of the soldered pin and hole arrangement of FIG. 1B.

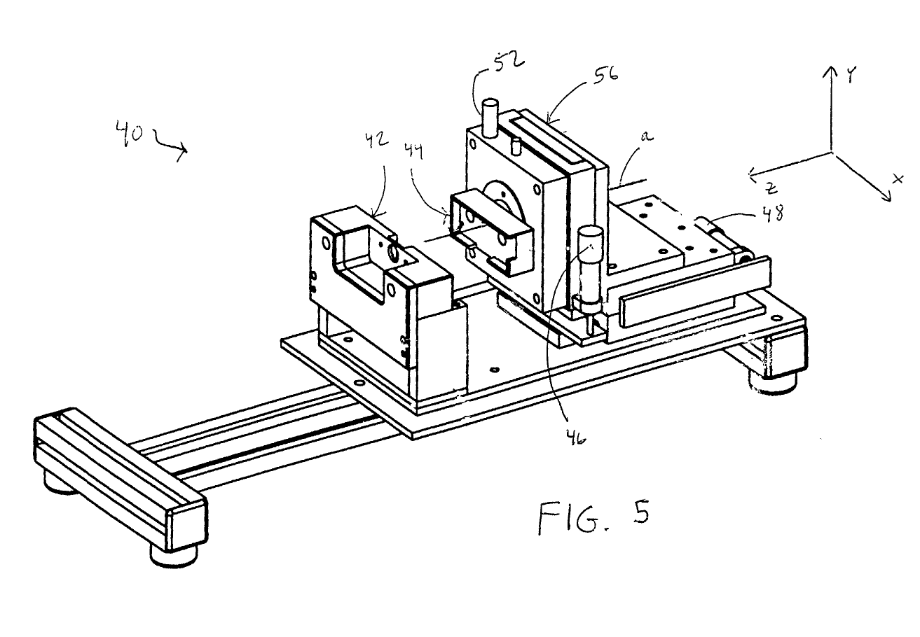

Details of a possible method for assembly of an optical and image sensor assembly are described with reference to FIG. 5 showing a mounting fixture 40 for mounting of an optical subassembly relative to an image sensor subassembly. Mounting fixture 40 includes optical subassembly mount 42 for holding an optical subassembly 12 and image sensor subassembly mount 44 for holding an image sensor subassembly 14. In the example shown, image sensor subassembly mount 42 is adapted to be moved in the Y direction (vertical) by the operation of knob 46, in the X direction (horizontal) by the operation of knob 48, and rotationally about axis “a” of mount 44 by the operation of knob 52. In addition, chassis 56 which includes mount 44 may be moved in the Z direction by imparting a Z direction force at any point on chassis 56, including at any one of the knobs 46, 48 or 52. Since the operation of mounting fixtures of the general configuration of fixture 40 is well known to skilled artisans in various manufacturing arts, such operation will not be discussed further herein.

For mounting of an optical subassembly on an image sensor subassembly, an assembly station worker positions image sensor subassembly 12 in mount 42 and optical subassembly 14 in mount 44 and then engages the assemblies by directing the image sensor subassembly toward the optical subassembly by imparting a Z direction force on chassis 56. Engagement of the subassemblies is established in the specific example illustrated when pins 26 protrude through holes 28 as is best seen in FIG. 1B. Then, an assembly station worker adjusts the relative position of the subassemblies 12 and 14 while observing indicia corresponding to electrical signals generated by image sensor 22 until desired electrical signals are generated. An assembly station worker may adjust knob 48 for horizontal adjustment, knob 52 for rotational adjustment, and by mount 46 for vertical adjustment.

To facilitate observation of indicia corresponding to electrical signals generated by image sensor 22 (not shown), the output of image sensor 22 may be processed by a processor and an indicia representing the output may be displayed by a display monitor (not shown). Indicia which may be displayed by a display monitor may comprise, for example, oscilloscope traces corresponding to the output of a row or rows of pixels of a sensor array 22, representations of a bit map captured by a processor, a standard video output, or a combination of such outputs. Meanwhile, a predetermined test target may be positioned forward of mount 42 during the alignment process. The predetermined test target is designed to result in a pattern of electrical signals having detectable characteristics being generated by image sensor 22 when optical and imaging components of the subassemblies 12 and 14 are satisfactorily aligned. The predetermined test pattern may be illuminated by an illumination system which corresponds to the illumination system of the reader in which the assembly will be installed. In addition, emit and receive optical elements corresponding to the reader in which assembly 10 will be installed may be positioned forward of mount 42 during the alignment process.

Satisfactory alignment between a lens and a pixel plane, or between other optical and imaging components, will be indicated by a pattern of electrical signals having characteristics indicating alignment between optical and imaging elements being generated by image sensor 22. Alignment between the subassemblies is determined to be established when image sensor 22 generates electrical signals indicative of alignment between optical and imaging components of the subassemblies. When alignment is established, an assembly line worker solders the optical and image sensor subassemblies together at any solder-receiving interfaces defined between the solderable surfaces of the subassemblies 12 and 14. Among other benefits described in detail herein, the use of solder to bond the subassemblies is fast, allows for easy detachment of the subassemblies if needed, and does not require that any substantial external forces be applied to the subassemblies.

While this invention has been described in detail with reference to a preferred embodiment, it should be appreciated that the present invention is not limited to that precise embodiment. Rather, in view of the present disclosure which describes the best mode for practicing the invention, many modifications and variations would present themselves to those skilled in the art without departing from the scope and spirit of this invention, as defined in the following claims.

What is claimed is:

1. A method for mounting an optical subassembly of an optical reading device to an image sensor subassembly of an optical reading device, said method comprising the steps of:
moving said optical and image sensor subassemblies in proximity with one another; and
soldering said optical and image sensor assemblies together using a solder material.

2. The method of claim 1, further comprising the step of forming a solderable surface on at least one of said optical subassemblies or said image sensor subassemblies.

3. The method of claim 1, further comprising the step of forming a solderable surface on at least one of said optical subassemblies or said image sensor subassemblies, wherein said forming step includes the step of overmolding non-solderable material onto solderable material to form said solderable surface.

4. The method of claim 1, further comprising the step of forming a solderable surface on at least one of said optical or image sensor subassemblies, wherein said forming step includes the step of plating a solderable material onto a non-solderable material.

5. The method of claim 1, further comprising the step of forming a solderable material on at least one of said optical or image sensor subassemblies, wherein said forming step includes the step of insert molding solderable material in non-solderable material.

6. The method of claim 1, further comprising the step of forming a solderable surface on said optical subassembly, wherein said forming step includes the step of making a frame for said optical subassembly comprising essentially solderable material.

7. The method of claim 1, further comprising the step of forming a solderable surface on at least one of said optical subassemblies or said image sensor subassemblies, wherein said forming step includes the step of making said solderable surface in an irregular configuration having an increased surface area per unit three dimensional space relative to that of a smooth surface.

8. The method of claim 7, wherein said at least one solderable surface is in the configuration of a pin.

9. The method of claim 7, when said at least one solderable surface is in the configuration of a threaded screw.

10. The method of claim 7, wherein said at least one solderable surface is in the configuration of a hole.

11. The method of claim 1, further comprising the step of forming a first solderable surface on one of said subassemblies and a second solderable surface in said other of said subassemblies, wherein said first solderable surface is in made in the configuration of a pin, and said second solderable surface is made in the configuration of a hole, wherein said pin has a diameter smaller than said hole to allow positional adjusting of said optical subassembly relative to said image sensor subassembly.

12. The method of claim 1, further comprising the steps of forming a solderable pin on one of said subassemblies, and making a hole for receiving said pin on the remaining of said subassemblies.

13. A method for mounting an optical subassembly to an image sensor subassembly, said method comprising the steps of:
forming at least one solderable surface on at least one of said optical and image sensor subassemblies;
moving said optical subassembly in proximity with said image sensor subassembly to define an interface delimited by said at least one solderable surface of said optical subassembly or said image sensor subassembly; and
soldering said optical subassembly and said image sensor subassembly together at said interface.

14. The method of claim 13, wherein said forming step includes the step of overmolding non-solderable material onto solderable material.

15. The method of claim 13, wherein said forming step includes the step of plating a solderable material onto non-solderable material.

16. The method of claim 13, wherein said forming step includes the step of insert molding solderable material in non-solderable material.

17. The method of claim 13, wherein said forming step includes the step of making a frame for said optical subassembly comprising essentially solderable material.

18. The method of claim 13, wherein said forming step includes the step of making said solderable surface in an irregular configuration having an increased surface area per unit three dimensional space relative to that of a smooth surface.

19. The method of claim 18, wherein said at least one solderable surface is in the configuration of a pin.

20. The method of claim 18 wherein said at least one solderable surface is provided by a threaded screw.

21. The method of claim 18 wherein said at least one solderable surface is in the configuration of a hole.

22. The method of claim 13, wherein said forming step includes the step of making a first solderable surface in one of said subassemblies and a second solderable surface in said other of said subassemblies, wherein said first solderable surface is in made in the configuration of a pin, and said second solderable surface is made in the configuration of a hole having a diameter larger than said pin.

23. The method of claim 13, when said forming step includes the steps of forming a solderable pin on one of said subassemblies and a hole for receiving said pin on said other of said subassemblies.

24. The method of claim 13, wherein said moving step includes the step of aligning optical elements of said optical assembly with imaging elements of said image sensor assembly.

25. The method of claim 24, wherein said aligning step includes the steps of:
exposing said image sensor assembly to a predetermined test target; and
observing indicia representing electrical signals generated by said image sensor.

26. An image sensor subassembly comprising:
a substantially rigid member;
an image sensor chip disposed on said substantially rigid member; and
a solderable surface formed on said substantially rigid member.

27. The image sensor subassembly of claim 26, wherein said solderable surface is made in an irregular configuration having an increased surface area per unit three dimensional space relative a smooth surface.

28. The image sensor subassembly of claim 26, wherein said solderable surface is made in the configuration of a hole.

29. The image sensor subassembly of claim 26, wherein said solderable surface is in the configuration of a pin.

30. The image sensor subassembly of claim 26, wherein said solderable surface is provided by a threaded screw.

31. The image sensor subassembly of claim 26, wherein said at least one solderable surfaces includes four solderable surfaces formed about a periphery of said image sensor.

32. An optical subassembly comprising:
a substantially rigid member;
an optical element disposed on said substantially rigid member; and
a solderable surface formed on said substantially rigid member.

33. The optical subassembly of claim 32, wherein said solderable surface is made in an irregular configuration having an increased surface area per unit three dimensional space relative to that of a smooth surface.

34. The optical subassembly of claim 32, wherein said solderable surface is made in the configuration of a hole.

35. The optical subassembly of claim 33, wherein said solderable surface is in the configuration of a pin.

36. The optical subassembly of claim 33 wherein said solderable surface is provided by a threaded screw.

37. The optical subassembly of claim 33, wherein said at least one solderable surfaces includes four solderable surfaces formed about a periphery of said image sensor.

38. An optical reading device comprising:
an optical and image sensor assembly including an image sensor subassembly including an image sensor disposed on a substantially rigid member,
an optical subassembly engaged with said image sensor subassembly, said optical subassembly including an optical element disposed on a substantially rigid member,
at least one solderable surface formed on either of said image sensor or optical subassemblies defining at least one solder receiving interface between said image sensor subassembly and said optical subassembly,
solder material for bonding said subassemblies disposed at said at least one solder-receiving interface; and
a housing, said optical and image sensor assembly being disposed in said housing.

39. The device of claim 38, wherein said housing partially defines a feed path and wherein said device is a document reading device, for reading indicia from documents transported along said feed path.

40. The device of claim 38, wherein said housing includes a handle, and wherein said device is a hand held optical reader.

41. The optical subassembly of claim 38, wherein said at least one solderable surface is made in an irregular configuration having an increased surface area per unit three dimensional space relative to that of a smooth surface.

42. The optical subassembly of claim 38, wherein said at least one solderable surface is made in the configuration of a hole.

43. The optical subassembly of claim 38, wherein said at least one solderable surface is in the configuration of a pin.

44. The optical subassembly of claim 38, wherein said at least one solderable surface is provided by a threaded screw.
